(19) United States
(12) Patent Application Publication
(10) Pub. No.: US 2026/0194578 A1
(43) Pub. Date: Jul. 9, 2026

(54) Battery Deterioration State Estimation Method and Battery Deterioration State Estimation Device

(71) Applicants: NISSAN MOTOR CO., LTD., Yokohama-shi, Kanagawa-ku (JP); RENAULT S.A.S., Boulogne-Billancourt (FR)

(72) Inventors: Mitsunori Kumada, Kanagawa (JP); Tetsuya Mashio, Kanagawa (JP)

(21) Appl. No.: 19/133,123

(22) PCT Filed: Nov. 29, 2022
(86) PCT No.: PCT/IB2022/000686

§ 371 Date: May 27, 2025

(51) Int. Cl. G01R 31/367; G01R 31/389; G01R 31/392

(52) U.S. Cl. CPC G01R 31/367; G01R 31/389; G01R 31/392

(57) ABSTRACT

A controller constructs a model that has measured value information including an AC resistance value measured for learning and use history information acquired for learning as explanatory variables and a deterioration state measured for learning as a response variable. The controller estimates, using the constructed model, a deterioration state of a battery with measured value information including an AC resistance value measured for estimation and use history information acquired for estimation as explanatory variables and a deterioration state of the battery as a response variable.

### TECHNICAL FIELD

The present invention relates to a battery deterioration state estimation method and a battery deterioration state estimation device.

### BACKGROUND

In JP 2018-132369 A, storing in advance a correspondence relation among a temperature history, input/output resistance, and a full charge capacity of a secondary battery and estimating a full charge capacity of the secondary battery from a temperature history and input/output resistance of the secondary battery are proposed.

### SUMMARY

Since how the battery has been used can hardly be understood based on only a temperature history, it is difficult to accurately estimate the deterioration state of the battery only by taking the temperature history into consideration.

An object of the present invention is to improve estimation accuracy of a deterioration state in a battery.

According to one aspect of the present invention, a controller for learning executes processing of measuring an AC resistance value of a battery to be learned mounted on a vehicle by electro-chemical impedance spectroscopy and acquiring measured value information including at least a real axis component of the AC resistance value measured for learning. The controller for learning executes processing of acquiring use history information of the battery to be learned for learning. The controller for learning executes processing of measuring a deterioration state of the battery to be learned for learning. The controller for learning executes processing of constructing a model that has the measured value information measured for learning and the use history information acquired for learning as explanatory variables and the deterioration state measured for learning as a response variable. A controller for estimation executes processing of measuring an AC resistance value of a battery to be estimated by electro-chemical impedance spectroscopy and acquiring measured value information including at least a real axis component of the AC resistance value measured for estimation. The controller for estimation executes processing of acquiring use history information of the battery to be estimated for estimation. The controller for estimation executes processing of estimating, using the model, a deterioration state of the battery to be estimated with the measured value information measured for estimation and the use history information acquired for estimation as explanatory variables and the deterioration state of the battery to be estimated as a response variable.

According to the present invention, by taking into consideration use history information of a battery, estimation accuracy of a deterioration state in the battery can be improved.

### BRIEF DESCRIPTION OF THE DRAWINGS

FIG. 1 is a block diagram illustrative of a battery deterioration state estimation device;

FIG. 2 is a flowchart illustrative of learning processing;

FIG. 3 is a Nyquist plot of an AC resistance value;

FIG. 4 is a schematic diagram of e-dimensional data;

FIG. 5 is a schematic diagram of m-dimensional data;

FIG. 6 is a schematic diagram of a design matrix;

FIG. 7 is a schematic diagram of N-dimensional data;

FIG. 8 is a flowchart illustrative of estimation processing;

FIG. 9 is a diagram illustrative of a second embodiment; and

FIG. 10 is a diagram illustrative of a third embodiment.

### DETAILED DESCRIPTION

Embodiments of the present invention will be described below based on the drawings. Note that the respective drawings are schematic and do not necessarily depict the actual dimensions or precise configurations of practical implementation of the present invention. In addition, the following embodiments indicate a device and a method to embody the technical idea of the present invention by way of example, and the technical idea of the present invention does not limit the configuration of the constituent components to that described below. That is, the technical idea of the present invention can be subjected to a variety of alterations within the technical scope prescribed by the claims described in CLAIMS.

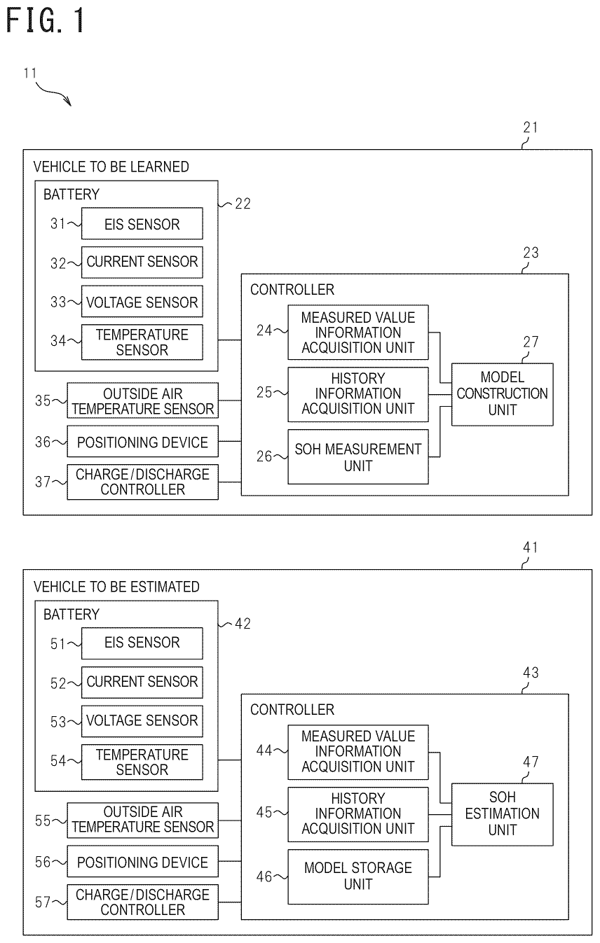

### First Embodiment

<Configuration> FIG. 1 is a block diagram illustrative of a battery deterioration state estimation device.

A battery deterioration state estimation device 11 includes a vehicle 21 to be learned and a vehicle 41 to be estimated. The vehicle 21 is an electric vehicle or a hybrid vehicle that is capable of traveling driven by a motor and includes a battery 22 (battery to be learned) and a controller 23 (controller for learning). Although the battery 22 is, for example, a lithium-ion battery that is used for driving a vehicle, the battery 22 may be a sodium ion battery or a solid-state battery.

In the battery 22, an EIS sensor 31, a current sensor 32, a voltage sensor 33, and a temperature sensor 34 are installed. The EIS sensor 31 measures an AC resistance value Z of the battery 22 by electro-chemical impedance spectroscopy (EIS). The current sensor 32 measures current I of the battery 22. The voltage sensor 33 measures voltage E of the battery 22. The temperature sensor 34 measures temperature Tb of the battery 22.

In the vehicle 21, an outside air temperature sensor 35, a positioning device 36, and a charge/discharge controller 37 are installed. The outside air temperature sensor 35 measures outside air temperature To. The positioning device 36 acquires position information of the vehicle 21 by GPS. The charge/discharge controller 37, when the battery 22 is charged, acquires charge type information indicating whether the charge is normal charge or quick charge and, when the battery 22 discharges, acquires discharge type information indicating whether the discharge is discharge due to traveling or discharge due to a use other than traveling, such as power supply to a home or a smart grid. The charge type information and the discharge type information can be acquired via the controller 23 of the vehicle 21, which will be described later, or a management device of a charger or a management device of a power supply destination.

The controller 23 is configured by, for example, a microcomputer and includes a measured value information acquisition unit 24, a history information acquisition unit 25, a deterioration state (SOH) measurement unit 26, and a model construction unit 27. The measured value information acquisition unit 24 acquires measured value information including at least a real axis component Zr of the AC resistance value Z acquired by the EIS sensor 31. The history information acquisition unit 25 acquires use history information of the battery 22. The SOH measurement unit 26 measures a deterioration state (SOH: State of Health) of the battery 22, using an existing method. The model construction unit 27 constructs a model that has measured value information measured for learning and use history information acquired for learning as explanatory variables and a deterioration state SOH measured for learning as a response variable, for each battery cell type.

The vehicle 41 includes a battery 42 (battery to be estimated) and a controller 43 (controller for estimation). The battery 42 is of the same battery cell type as the battery 22 mounted on the vehicle 21 serving as a vehicle to be learned. In the battery 42, an EIS sensor 51, a current sensor 52, a voltage sensor 53, and a temperature sensor 54 are installed. In the vehicle 41, an outside air temperature sensor 55, a positioning device 56, and a charge/discharge controller 57 are installed. The controller 43 includes a measured value information acquisition unit 44, a history information acquisition unit 45, a model storage unit 46, and a deterioration state (SOH) estimation unit 47. Detailed description of components common to the configuration of the vehicle 21 will be omitted. The model storage unit 46 stores a model constructed by the model construction unit 27. The SOH estimation unit 47 estimates, using the model, a deterioration state SOH of the battery 42 with measured value information measured for estimation and use history information acquired for estimation as explanatory variables and the deterioration state SOH as a response variable.

Next, learning processing that is executed by the controller 23 of the vehicle 21 serving as a vehicle to be learned will be described. Although the learning processing is processing executed every predetermined period, the processing is only required to be executed at a frequency of, for example, approximately once per week or once per month since deterioration of the battery 22 does not progress day by day, and it is needless to say that the execution frequency is not limited to such a frequency.

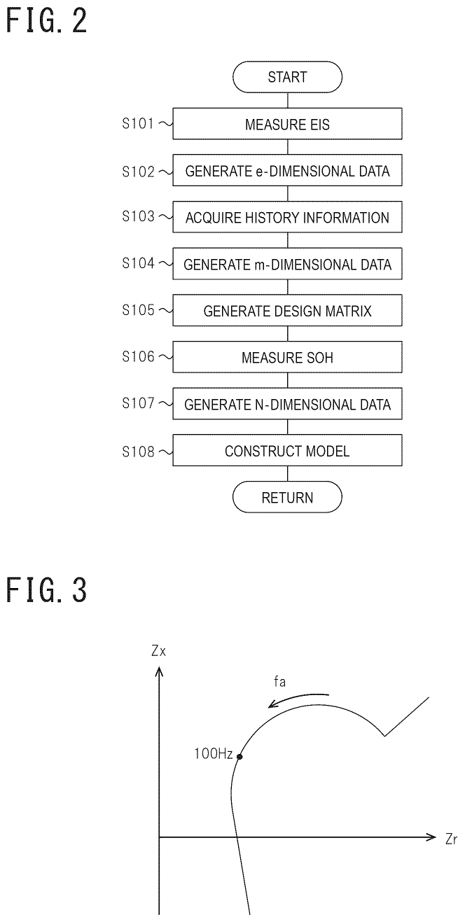

FIG. 2 is a flowchart illustrative of the learning processing. First, in step S101, an AC resistance value Z that is AC impedance of the battery 22 is measured by the EIS sensor 31. Although the measurement of the AC resistance value Z can be performed at an arbitrary timing, the measurement is preferably performed when the vehicle 21 is in a stationary state in which neither discharge due to traveling nor charge is performed and a predetermined time has elapsed since the vehicle 21 is parked, in order to increase measurement accuracy.

FIG. 3 is a Nyquist plot of the AC resistance value Z. In FIG. 3, the abscissa represents the real axis component Zr of the AC resistance value Z, the ordinate represents an imaginary axis component Zx of the AC resistance value Z, and the AC resistance value Z corresponding to a frequency fa is plotted. The AC resistance value Z to be measured is assumed to be an AC resistance value Z in a frequency band of 100 Hz or more where the real axis component Zr does not largely vary.

The description returns to FIG. 2. In the next step S102, e-dimensional data (first dimensional data) that have e feature amounts are generated from the measured value information measured for learning. Herein, e is a natural number of 1 or more. The measured value information includes at least the real axis component Zr of the AC resistance value Z. The measured value information may include, as an additional feature amount, any of the imaginary axis component Zx of the AC resistance value Z, a difference ΔZ between a DC resistance value DCR and the real axis component Zr of the AC resistance value Z, a state of charge SOC, and open-circuit voltage OCV.

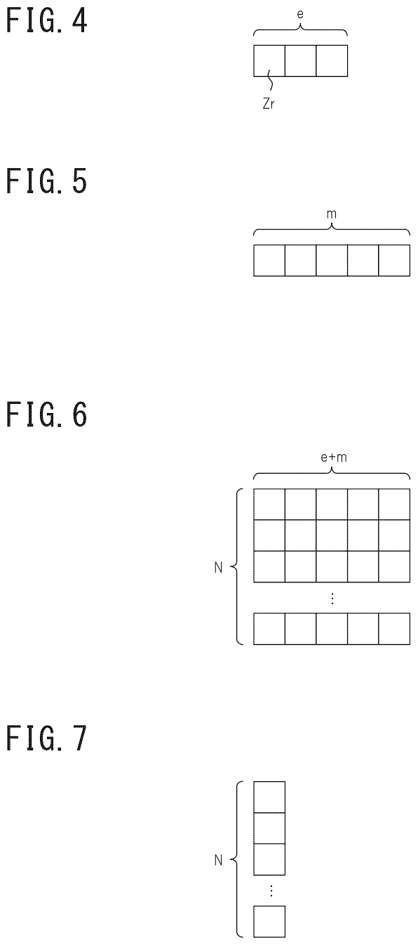

FIG. 4 is a schematic diagram of e-dimensional data. One feature amount is schematically represented by one square, and a plurality of feature amounts arranged in a row are illustrated. Herein, e-dimensional data including three feature amounts are illustrated as an example.

The description returns to FIG. 2. In the next step S103, use history information of the battery 22 is acquired. In the use history information, at least one of a battery maximum temperature Tb_{MAX} at the time of charge and discharge, dwell time Tstemp of the battery temperature within each of battery temperature bands during a parking period, dwell time Tssoc of the battery within each of state-of-charge bands during the parking period, a state of charge SOC at the start of charge and discharge, battery temperature Tb at the start of charge and discharge, charge/discharge current Qc, and a charge/discharge type is included. The use history information is retained as time series data that have, under the assumption that each of charge and discharge is an event, one or more feature amounts for each event. The discharge includes not only discharge due to traveling but also discharge due to power supply to a home or a smart grid. There is variation in cooling performance depending on a mounting position of a module, and when exposed to a high temperature environment, deterioration of the battery progresses. Therefore, with regard to the battery temperature, the mounting position of the module, statistic, such as a maximum value, an average, and variance, relating to the outside air temperature To, or region classification using average latitude information and modes of longitude and latitude among the position information of the vehicle 21 may be added. The battery temperature band is one of a low temperature band, an intermediate temperature band, and a high temperature band into which temperature is classified. The charge/discharge current Ic is a total during an event. Frequency of power supply being high means that cycle frequency of charge/discharge is high. In addition, variance in the state of charge SOC at the start of charge being high means that the state-of-charge SOC band (swing width) to be used is wide and the cycle frequency of charge/discharge is also high. Such a charge/discharge history serves as an index influencing the deterioration state SOH. To the use history information, a ratio of the afore-described discharge current due to power supply to total charge current or cell type information of the battery 22 serving as a battery to be learned may also be added.

In the next step S104, m-dimensional data (second dimensional data) that have m feature amounts are generated from the use history information acquired for learning. Herein, m is a natural number of 1 or more. Specifically, m-dimensional data are generated by performing statistical processing on the use history information retained as time series data. For example, statistics including a total, a maximum value, a minimum value, an average, a quartile, a mode, and a variance are used. A feature amount is selected using a feature amount selection means that is generally used in model learning, such as a feature amount of high importance being selected using a decision tree model or PFI and a feature amount being selected using a Lasso regression model.

FIG. 5 is a schematic diagram of m-dimensional data. One feature amount is schematically represented by one square, and a plurality of feature amounts arranged in a row are illustrated. Herein, m-dimensional data including five feature amounts are illustrated as an example.

The description returns to FIG. 2. In the next step S105, by collecting N pieces of (e+m)-dimensional data (third dimensional data) each of which are generated by combining a piece of e-dimensional data generated for learning and a piece of m-dimensional data generated for learning, a design matrix is generated. Herein, N is a natural number of e+m or more and the number of a lot of pieces of sample data that are required for machine learning, and N is required to be set to a large value in order to increase learning accuracy. On the design matrix, standardization processing, such as operation of setting an average to 0 and a variance to 1, operation of setting a median value to 0 and an interquartile range to 1, and operation of limiting a range in which a variable has a value to a specific section, may be performed and processing using nonlinear conversion through logarithmization may be further performed.

FIG. 6 is a schematic diagram of a design matrix. By generating a piece of (e+m)-dimensional data by arranging a piece of e-dimensional data generated for learning and a piece of m-dimensional data generated for learning in a row and arranging N pieces of such (e+m)-dimensional data in a column, a design matrix of N rows and e+m columns is generated.

The description returns to FIG. 2. In the next step S106, a deterioration state SOH of the battery 22 is measured for learning. Herein, as an existing method, the deterioration state SOH of the battery 22 is measured by, for example, measuring a cumulative discharge amount from a fully charged state.

In the next step S107, N-dimensional data (fourth dimensional data) are generated from N deterioration states SOH measured for learning. The number of elements in the N-dimensional data corresponds to the number of rows of the design matrix.

FIG. 7 is a schematic diagram of N-dimensional data. One deterioration state SOH is schematically represented by one square, and a plurality of deterioration states SOH arranged in a column are illustrated.

The description returns to FIG. 2. In the next step S108, a model that has the design matrix generated for learning as an explanatory variable and the N-dimensional data generated for learning as a response variable is constructed and stored. A model is constructed for each battery cell type. Since the deterioration state SOH is generally represented in a range SOH={SOH|0<SOH<1}, it may be configured such that a regression model having z that is obtained by performing logit transformation expressed by Math 1 below, that is, z={z|−∞<z<∞}, as a response variable is trained. Because of this configuration, it is possible to avoid a situation where a value obtained by estimating the deterioration state SOH using a model is less than 0 or exceeds 1. Although a Gaussian process regression model using a kernel function is employed herein, the type of the model is not limited to the Gaussian process regression model. As a machine learning algorithm, Lasso regression, elastic net regression, support vector regression, random forest, neural network, or the like may be employed.

$$\begin{matrix}z = logit ( SOH ) \\ = log ( \frac{SOH}{1 - SOH} )\end{matrix} \qquad [ Math 1 ]$$

Note that when the number of pieces of (e+m)-dimensional data and the number of elements in the N-dimensional data are less than N, the process returns to a main program without performing anything. Therefore, until the number of pieces of (e+m)-dimensional data and the number of elements in the N-dimensional data reach N, the process becomes a loop process in which the processing in steps S101 to S107 is repeated. At a time point when the number of pieces of (e+m)-dimensional data and the number of elements in the N-dimensional data reach N, an initial model is constructed. At and after the time point, by increasing the number of pieces of (e+m)-dimensional data and the number of elements in the N-dimensional data or updating a piece of (e+m)-dimensional data and a corresponding element in the N-dimensional data, a trained model is updated.

The foregoing is the learning processing that is performed by the controller 23. Among the processing, the processing in step S101 corresponds to the processing executed by the measured value information acquisition unit 24, and the processing in step S103 corresponds to the processing executed by the history information acquisition unit 25. In addition, the processing in step S106 corresponds to the processing executed by the SOH measurement unit 26, and the processing in step S108 corresponds to the processing executed by the model construction unit 27.

Next, estimation processing that is performed by the controller 43 of the vehicle 41 serving as a vehicle to be estimated will be described. Although the estimation processing is processing executed every predetermined period, the processing is only required to be executed at a frequency of, for example, approximately once per week or once per month since deterioration of the battery 42 does not progress day by day, and it is needless to say that the execution frequency is not limited to such a frequency.

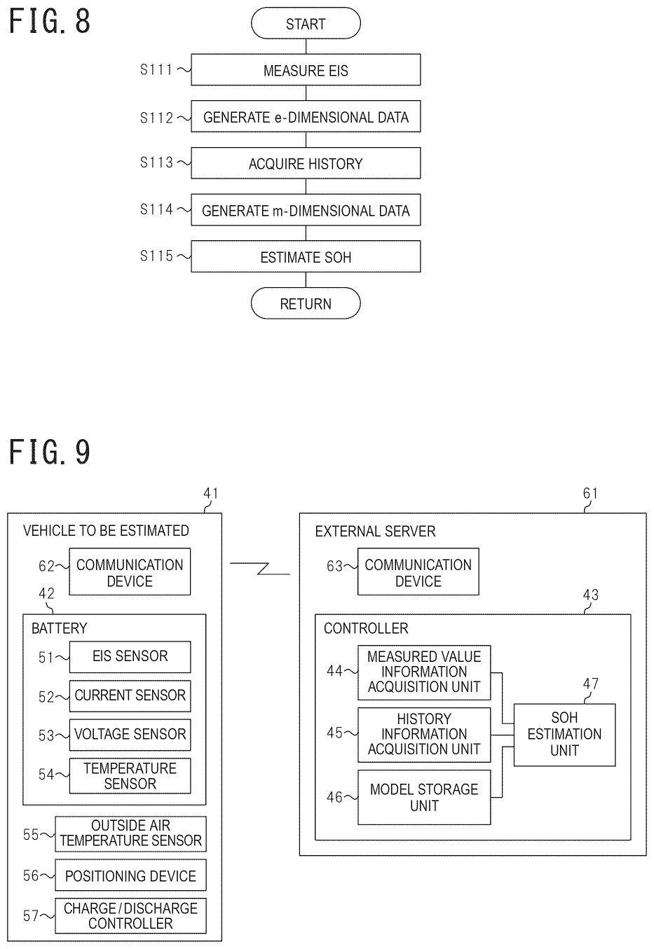

FIG. 8 is a flowchart illustrative of the estimation processing. First, in step S111, an AC resistance value Z that serves as AC impedance of the battery 42 is measured by the EIS sensor 51. The idea of the processing is the same as that of the processing in step S101 at the time of learning.

In the next step S112, e-dimensional data (first dimensional data) that have e feature amounts are generated from measured value information measured for estimation. The idea of the processing is the same as that of the processing in step S102 at the time of learning.

In the next step S113, use history information of the battery 42 is acquired. The idea of the processing is the same as that of the processing in step S103 at the time of learning.

In the next step S114, m-dimensional data (second dimensional data) that have m feature amounts are generated from the use history information acquired for estimation. The idea of the processing is the same as that of the processing in step S104 at the time of learning.

In the next step S115, a deterioration state SOH of the battery 42 is estimated using the model stored in the model storage unit 46. That is, as expressed by Math 2 below, estimation is performed with (e+m)-dimensional data (third dimensional data) that are generated by combining the e-dimensional data generated for estimation and the m-dimensional data generated for estimation as an explanatory variable and the deterioration state SOH of the battery 42 as a response variable.

$$\text{?} = f ( {x}_{1} , {x}_{2} , … {x}_{e + m} ) \qquad [ Math 2 ]$$

When the logit transformation is performed at the time of learning, by performing inverse logit transformation expressed by Math 3 below on an estimated value from a trained regression model, a deterioration state SOH represented in a range SOH={SOH|0<SOH<1} can be obtained.

$$\begin{matrix}\text{?} = {inv}_{l ogit ( \hat{z} )} \\ = \frac{exp ( \hat{z} )}{1 + exp ( \hat{z} )}\end{matrix} \qquad [ Math 3 ]$$

The foregoing is the estimation processing that is executed by the controller 43. Among the processing, the processing in step S111 corresponds to the processing executed by the measured value information acquisition unit 44, the processing in step S113 corresponds to the processing executed by the history information acquisition unit 45, and the processing in step S115 corresponds to the processing executed by the SOH estimation unit 47.

### Advantageous Effects

Next, major advantageous effects of the first embodiment will be described.
(1) The controller 23 executes processing of measuring an AC resistance value Z of the battery 22 used for driving a vehicle by electro-chemical impedance spectroscopy and acquiring measured value information including at least the real axis component Zr of the AC resistance value Z measured for learning. The controller 23 executes processing of acquiring use history information of the battery 22 for learning and processing of measuring the deterioration state SOH of the battery 22 for learning. The controller 23 executes processing of constructing a model that has the measured value information measured for learning and the use history information acquired for learning as explanatory variables and the deterioration state SOH measured for learning as a response variable. Although a deterioration mode differs depending on a use of the battery 22, performing machine learning in consideration of the use history information of the battery 22 enables a model that improves estimation accuracy of the deterioration state SOH to be constructed. The controller 43 executes processing of measuring an AC resistance value Z of the battery 42 used for driving a vehicle by electro-chemical impedance spectroscopy and acquiring measured value information including at least the real axis component Zr of the AC resistance value Z measured for estimation. The controller 43 executes processing of acquiring use history information of the battery 42 for estimation. The controller 43 executes processing of estimating, using the model, a deterioration state SOH of the battery 42 with the measured value information measured for estimation and the use history information acquired for estimation as explanatory variables and the deterioration state SOH of the battery 42 as a response variable. Although a deterioration mode differs depending on a use of the battery 42, taking into consideration the use history information of the battery 42 enables estimation accuracy of the deterioration state SOH in the battery 42 to be improved.
(2) The measured value information includes, in addition to the real axis component Zr, at least one of the imaginary axis component Zx of the AC resistance value Z, a difference ΔZ between a DC resistance value DCR and the real axis component Zr, a state of charge SOC, and open-circuit voltage OCV. Taking into consideration a feature amount capable of representing change in a Nyquist plot in addition to the real axis component Zr enables the estimation accuracy of the deterioration state SOH to be further improved. In addition, a value equivalent to electrode resistance can be simulated as interfacial resistance. In addition, influence of electronic and ionic conduction due to positive/negative electrode volume change can be taken into consideration.
(3) In the use history information, at least one of a battery maximum temperature Tb_{MAX} at the time of charge and discharge, dwell time Tstemp of the battery temperature within each of battery temperature bands during a parking period, dwell time Tssoc of the battery within each of state-of-charge bands during the parking period, a state of charge SOC at the start of charge and discharge, battery temperature Tb at the start of charge and discharge, an amount of charge/discharge current Qc, and a charge/discharge type is included. Because of this configuration, by taking into consideration a factor influencing the deterioration state SOH and using more limited data, a calculation load can be reduced and estimation accuracy of the deterioration state SOH can be improved.
(4) The AC resistance value Z is measured in a frequency band of 100 Hz or more. Because of this configuration, an electrolyte resistance component among the AC resistance value Z that has a high correlation with the deterioration state SOH can be measured.
(5) The controller 23 executes processing of generating e-dimensional data that have e feature amounts from measured value information measured for learning and processing of generating m-dimensional data that have m feature amounts from use history information acquired for learning. The controller 23 executes processing of collecting N pieces of (e+m)-dimensional data each of which are generated by combining a piece of e-dimensional data generated for learning and a piece of m-dimensional data generated for learning, the N being greater than or equal to e+m, and thereby generating a design matrix. The controller 23 executes processing of generating N-dimensional data from N deterioration states SOH measured for learning. The controller 23 constructs a model based on the design matrix generated for learning and the N-dimensional data generated for learning. Because of this configuration, by performing machine learning in consideration of the use history information of the battery 22, a model that improves estimation accuracy of the deterioration state SOH can be constructed. The controller 43 executes processing of generating e-dimensional data that have e feature amounts from measured value information measured for estimation and processing of generating m-dimensional data that have m feature amounts from use history information acquired for estimation. The controller 43 estimates, using the model, a deterioration state SOH from (e+m)-dimensional data that are generated by combining the e-dimensional data generated for estimation and the m-dimensional data generated for estimation. Because of this configuration, by taking into consideration the use history information of the battery 42, estimation accuracy of the deterioration state SOH in the battery 42 can be improved.

The controller 23 constructs a model for each battery cell type. This is because influence of various types of feature amounts on the deterioration state SOH differs for each battery cell type. Therefore, constructing a model for each battery cell type enables a model improving estimation accuracy to be constructed.

The controller 23 is installed in the vehicle 21 to be learned, and the controller 43 is installed in the vehicle 41 to be estimated. Because of this configuration, primary data can be directly referred to, and it becomes possible to perform calculation using data of high temporal resolution and high information resolution during a use period of the vehicle. Therefore, it becomes possible to estimate the deterioration state SOH with high accuracy.

Next, a comparative example will be described.

Herein, a configuration to estimate a deterioration state SOH of a battery in consideration of an AC resistance value Z measured by an EIS sensor and a temperature history of the battery is used as a comparative example. Even when the temperature history is taken into consideration, when the battery is used in such a manner that charge and discharge are frequently repeated, a correlation between the AC resistance value Z and the deterioration state SOH is caused to change. To this phenomenon, occurrence of electrodeposition of lithium, isolation of active material due to cut-off of a conduction path for ions and electrons, and deactivation of a reaction surface are related. Therefore, since how the battery has been used can hardly be understood based on only a temperature history, it is difficult to accurately estimate the deterioration state SOH of the battery only by taking a temperature history into consideration. In addition, since even when correction is performed by use of a standard calibration curve using the AC resistance value Z, a plurality of factors, such as a state of charge SOC, a temperature history, and a load cycle, influence deterioration of a battery in a complex manner, representation by a simple linear regression model has been insufficient.

### Second Embodiment

<Configuration> A second embodiment is an embodiment in which a controller 43 configured to perform estimation of a deterioration state SOH is installed in an external server. Since the other constituent components are the same as the afore-described first embodiment, detailed description of components common to the first embodiment will be omitted.

FIG. 9 is a diagram illustrative of the second embodiment. In the second embodiment, an external server 61 is disposed, and the controller 43 is installed in the external server 61. A communication device 62 is installed in a vehicle 41, and the communication device 62 communicates with the external server 61 through the Internet. A communication device 63 is installed in the external server 61, and the communication device 63 communicates with the vehicle 41 through the Internet. The controller 43 receives various types of information measured in the vehicle 41, estimates a deterioration state SOH, and transmits an estimation result to the vehicle 41.

### Advantageous Effects

Next, major advantageous effects of the second embodiment will be described.
(1) The controller 43 is installed in the external server 61 communicable with the vehicle 41. Because of this configuration, it is possible to, while reducing a load and data capacity required for calculation performed in the vehicle 41, improve estimation accuracy of the deterioration state SOH. In addition, since a model that is updated in a cloud environment can be used, the estimation accuracy of the deterioration state SOH can be improved.

Other advantageous effects achieved by common constituent components are the same as the afore-described first embodiment.

### <Variation>

Although in the second embodiment, the configuration in which only the controller 43, which is configured to estimate the deterioration state SOH, is installed in the external server is described, the present invention is not limited to the configuration. That is, a controller 23 that constructs a model may also be installed in an external server communicable with the vehicle 21. Because of this configuration, it is possible to construct a model capable of improving estimation accuracy of the deterioration state SOH while reducing a load and data capacity required for calculation performed in the vehicle 21. In addition, since a design matrix generated for learning and N-dimensional data generated for learning can be updated in the cloud environment, a model improving the estimation accuracy of the deterioration state SOH can be constructed. In addition, since measured value information and use history information provided from a plurality of vehicles 21 can be referred to in an integrated manner, a model improving the estimation accuracy of the deterioration state SOH can be constructed.

### Third Embodiment

<Configuration> A third embodiment is an embodiment in which a controller 43 configured to perform estimation is installed in an external server and estimates a deterioration state SOH of a battery 42 removed from a vehicle 41. Since the other constituent components are the same as the afore-described first embodiment, detailed description of components common to the first embodiment will be omitted.

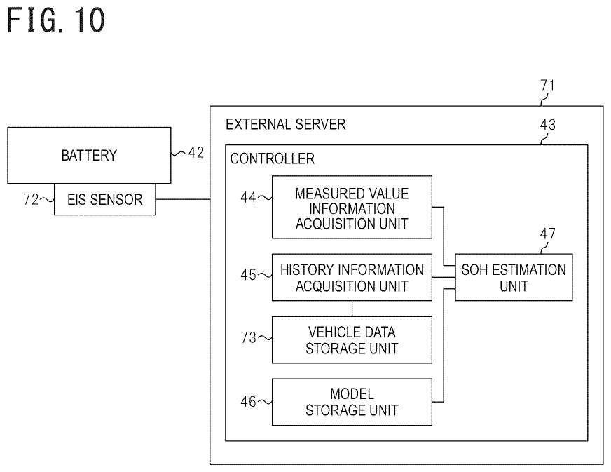

FIG. 10 is a diagram illustrative of the third embodiment. In the third embodiment, an external server 71 is disposed, and the controller 43 is installed in the external server 71. To the battery 42 removed from the vehicle 41, an EIS sensor 72 is attached. A measured value information acquisition unit 44 acquires measured value information including at least a real axis component Zr of an AC resistance value Z acquired by the EIS sensor 72. The controller 43 includes a vehicle data storage unit 73. The vehicle data storage unit 73 stores use history information of a battery 22. A history information acquisition unit 45 acquires use history information of the battery 22 from the vehicle data storage unit 73. Note that although the AC resistance value Z is measured by the EIS sensor 72, the present invention is not limited to the configuration. That is, when an AC resistance value Z that was measured last by the vehicle 41 can be acquired from the vehicle data storage unit 73, this acquired AC resistance value Z can be used. In addition, it is needless to say that with regard to a used battery to which no EIS sensor 72 is attached, resistance may be measured by an EIS measurement device that is installed off-line (in a non-in-vehicle state or in a so-called off-board manner).

### Advantageous Effects

Next, major advantageous effects of the third embodiment will be described.
(1) The controller 43 estimates the deterioration state SOH of the battery 42 removed from the vehicle 41. Because of this configuration, estimation accuracy of the deterioration state SOH of the used battery 42 can also be improved. As a result, reuse of the battery 42 can be facilitated.

Other advantageous effects achieved by common constituent components are the same as the afore-described first embodiment.

While the present invention has been described herein referring to a limited number of embodiments, the scope of the present invention is not limited to the embodiments, and modifications and variations of the embodiments based on the above-described disclosure are apparent to a person skilled in the art.

### REFERENCE SIGNS LIST

11 Battery deterioration state estimation device
21 Vehicle
22 Battery
23 Controller
24 Measured value information acquisition unit
25 History information acquisition unit
26 SOH measurement unit
27 Model construction unit
31 EIS sensor
32 Current sensor
33 Voltage sensor
34 Temperature sensor
35 Outside air temperature sensor
36 Positioning device
37 Charge/discharge controller
41 Vehicle
42 Battery
43 Controller
44 Measured value information acquisition unit
45 History information acquisition unit
46 Model storage unit
47 SOH estimation unit
51 EIS sensor
52 Current sensor
53 Voltage sensor
54 Temperature sensor
55 Outside air temperature sensor
56 Positioning device
57 Charge/discharge controller
61 External server
62 Communication device
63 Communication device
71 External server
72 EIS sensor
73 Vehicle data storage unit

1. A battery deterioration state estimation method causing a controller for learning to execute processing comprising:
measuring an AC resistance value of a battery to be learned used for driving a vehicle by electro-chemical impedance spectroscopy and acquiring measured value information including at least a real axis component of the AC resistance value measured for learning;
acquiring use history information of the battery to be learned for learning;
measuring a deterioration state of the battery to be learned for learning; and
constructing a model having the measured value information measured for learning and the use history information acquired for learning as explanatory variables and the deterioration state measured for learning as a response variable and
causing a controller for estimation to execute processing comprising:
measuring an AC resistance value of a battery to be estimated used for driving a vehicle by electro-chemical impedance spectroscopy and acquiring measured value information including at least a real axis component of the AC resistance value measured for estimation;
acquiring use history information of the battery to be estimated for estimation; and
estimating, using the model, a deterioration state of the battery to be estimated with the measured value information measured for estimation and the use history information acquired for estimation as explanatory variables and a deterioration state of the battery to be estimated as a response variable,
wherein the use history information is time series data that has, under an assumption that each of charge and discharge of the battery is an event, one or more feature amounts for each event.

2. The battery deterioration state estimation method according to claim 1, wherein in the measured value information, in addition to the real axis component, at least one of an imaginary axis component of the AC resistance value, a difference between a DC resistance value and the real axis component, a state of charge, and open-circuit voltage is included.

3. The battery deterioration state estimation method according to claim 1, wherein in the use history information, at least one of a battery maximum temperature at a time of charge and discharge, dwell time of a battery temperature within each of battery temperature bands during a parking period, dwell time of the battery within each of state-of-charge bands during a parking period, a state of charge at start of charge and discharge, battery temperature at start of charge and discharge, an amount of charge/discharge current, and a charge/discharge type is included.

4. The battery deterioration state estimation method according to claim 1, wherein the AC resistance value is measured in a frequency band of 100 Hz or more.

5. The battery deterioration state estimation method according to claim 1, wherein
the controller for learning executes processing including:
generating first dimensional data, the first dimensional data having a prescribed number of feature amounts, from the measured value information measured for learning;
generating second dimensional data, the second dimensional data having a prescribed number of feature amounts, from the use history information acquired for learning;
collecting a plurality of pieces of third dimensional data, each piece of the third dimensional data being generated by combining a piece of the first dimensional data generated for learning and a piece of the second dimensional data generated for learning, and generating a design matrix; and
generating fourth dimensional data from a plurality of deterioration states measured for learning and
constructs the model based on the design matrix generated for learning and the fourth dimensional data generated for learning, and
the controller for estimation executes processing including:
generating first dimensional data, the first dimensional data having a prescribed number of feature amounts, from the measured value information measured for estimation; and
generating second dimensional data, the second dimensional data having a prescribed number of feature amounts, from the use history information acquired for estimation and
estimates, using the model, the deterioration state from third dimensional data, the third dimensional data being generated by combining the first dimensional data generated for estimation and the second dimensional data generated for estimation.

6. The battery deterioration state estimation method according to claim 1, wherein the controller for learning constructs the model for each battery cell type.

7. The battery deterioration state estimation method according to claim 1, wherein at least one of the controller for learning and the controller for estimation is installed in a vehicle.

8. The battery deterioration state estimation method according to claim 1, wherein at least one of the controller for learning and the controller for estimation is installed in an external server communicable with a vehicle.

9. The battery deterioration state estimation method according to claim 1, wherein the controller for estimation estimates a deterioration state of the battery to be estimated removed from a vehicle.

10. A battery deterioration state estimation device comprising:
a controller for learning configured to execute processing including:
measuring an AC resistance value of a battery to be learned used for driving a vehicle by electro-chemical impedance spectroscopy and acquiring measured value information including at least a real axis component of the AC resistance value measured for learning;
acquiring use history information of the battery to be learned for learning;
measuring a deterioration state of the battery to be learned for learning; and
constructing a model having the measured value information measured for learning and the use history information acquired for learning as explanatory variables and the deterioration state measured for learning as a response variable; and
a controller for estimation configured to execute processing including:
measuring an AC resistance value of a battery to be estimated used for driving a vehicle by electro-chemical impedance spectroscopy and acquiring measured value information including at least a real axis component of the AC resistance value measured for estimation;
acquiring use history information of the battery to be estimated for estimation; and
estimating, using the model, a deterioration state of the battery to be estimated with the measured value information measured for estimation and the use history information acquired for estimation as explanatory variables and a deterioration state of the battery to be estimated as a response variable,
wherein the use history information is time series data that has, under an assumption that each of charge and discharge of the battery is an event, one or more feature amounts for each event.

11. The battery deterioration state estimation method according to claim 1, wherein the use history information indicates how the battery has been used.

12. The battery deterioration state estimation method according to claim 1, wherein the use history information is time series data that indicates how the battery has been used.

13. (canceled)
